(19) United States
(12) Patent Application Publication
(10) Pub. No.: US 2026/0229454 A1
(43) Pub. Date: Aug. 6, 2026

(54) CHARGED PARTICLE BEAM WRITING METHOD AND CHARGED PARTICLE BEAM WRITING APPARATUS

(71) Applicant: NuFlare Technology, Inc., Yokohama-shi (JP)

(72) Inventors: Hiroshi MATSUMOTO, Yokohama-shi (JP); Yasuo KATO, Yokohama-shi (JP)

(73) Assignee: NuFlare Technology, Inc., Yokohama-shi (JP)

(21) Appl. No.: 19/435,984

(22) Filed: Dec. 30, 2025

(30) Foreign Application Priority Data
Jan. 31, 2025 (JP) 2025-015324

(51) Int. Cl. H01J 37/304; H01J 37/317

(52) U.S. Cl. CPC H01J 37/3045; H01J 37/3177; H01J 2237/31764; H01J 2237/31769; H01J 2237/31796

(57) ABSTRACT

According to one aspect of the present invention, a charged particle beam writing method for writing a plurality of patterns to be written assigned to any one of a plurality of pattern groups, the charged particle beam writing method includes: writing a plurality of patterns on a target object in accordance with the multiplicity set for each pattern group by using a charged particle beam by performing processing of writing each pattern of two or more pattern groups among the plurality of pattern groups in one travel in a predetermined direction of a stage on which the target object is placed and processing of writing no pattern of at least one pattern group less than the two or more pattern groups and writing a pattern of the remaining pattern group of the two or more pattern groups in one travel in the predetermined direction of the stage.

### CROSS-REFERENCE TO RELATED APPLICATION

This application is based upon and claims the benefit of priority from prior Japanese Patent Application No. 2025-015324 filed on Jan. 31, 2025 in Japan, the entire contents of which are incorporated herein by reference.

### BACKGROUND OF THE INVENTION

### Field of the Invention

The present invention relates to a charged particle beam writing method and a charged particle beam writing apparatus.

### Related Art

Lithography technology contributing to the progress of miniaturization of semiconductor devices, is a very important, and the only process to generate a pattern among semiconductor manufacturing processes. Recently, with the high integration of LSI, a circuit line width required for the semiconductor devices becomes finer year by year. Here, the electron beam writing (or “drawing”) technology inherently has excellent resolution, and writing is performed on a mask for wafer exposure, a wafer, or the like using an electron beam.

For example, there is a writing apparatus using multiple electron beams. As compared with a case of performing writing with one electron beam, irradiation of more beams can be performed at one time by using the multiple electron beams, so that the throughput can be greatly improved. In such a multiple beam writing apparatus, for example, electron beams emitted from an electron emission source assembly are passed through a mask having a plurality of holes to form multiple beams, each beam blanking-controlled and not shielded is reduced by an optical system, each beam is deflected by a deflector, and a desired position on a target object is irradiated with each beam. The multiple electron beam writing is performed by, for example, a raster method.

Irrespective of the case of using a single beam or the case of using multiple beams, in the electron beam writing, in addition to a main chip region in which a main pattern is arranged, peripheral chips in which a peripheral pattern whose writing accuracy may be lower than that of the main pattern is arranged are written. In addition, there may be a case where a frame pattern whose writing accuracy may be lower than that of the main pattern is written. These main chip, peripheral chips, and frames are generally merged and written together. In the raster-type writing method, a writing time is limited by a stage speed.

In such a case, a peripheral chip and a frame, which may have low writing accuracy, are written in addition to the main chip in a high-accuracy writing mode in which the stage speed is low in accordance with the main chip, so that the writing time increases. Such a problem becomes larger when multiple writing is performed. If the peripheral chips and the frames are not merged with the main chip and are written as a separate job, the writing can be performed in a low-accuracy mode with a high stage speed, but the writing time increases as the number of times of turning back of the stage or the like increases.

Here, it is disclosed that a chip in which patterns requiring high accuracy are merged and a chip in which patterns that may be low accuracy are merged are created, and after writing processing of one chip is completed, the writing processing of the other chip is performed, and that writing is performed while the multiplicity of multiple writing is changed for each chip (see Published Unexamined Japanese Patent Application No. 2011-243805 (JP-A- 2011-243805), for example). However, if the chip itself is changed, as described above, a separate job is performed for each chip, and the writing time increases as the number of times of turning back of the stage or the like increases.

### BRIEF SUMMARY OF THE INVENTION

According to one aspect of the present invention, a charged particle beam writing method for writing a plurality of patterns to be written assigned to any one of a plurality of pattern groups, the charged particle beam writing method includes:
setting a multiplicity of multiple writing to a value different for each pattern group of the plurality of pattern groups; and
writing a plurality of patterns on a target object in accordance with the multiplicity set for each pattern group by using a charged particle beam by performing
   processing of writing each pattern of two or more pattern groups among the plurality of pattern groups in one travel in a predetermined direction of a stage on which the target object is placed and
   processing of writing no pattern of at least one pattern group less than the two or more pattern groups and writing a pattern of the remaining pattern group of the two or more pattern groups in one travel in the predetermined direction of the stage.

According to another aspect of the present invention, a charged particle beam writing apparatus for writing a plurality of patterns to be written assigned to any one of a plurality of pattern groups, the charged particle beam writing apparatus includes:
a setting circuit configured to set a multiplicity of multiple writing to a value different for each pattern group of the plurality of pattern groups; and
a writing mechanism configured to write a plurality of patterns on a target object in accordance with the multiplicity set for each pattern group by using a charged particle beam by performing
   processing of writing each pattern of two or more pattern groups among the plurality of pattern groups in one travel in a predetermined direction of a stage on which the target object is placed and
   processing of writing no pattern of at least one pattern group less than the two or more pattern groups and writing a pattern of the remaining pattern group of the two or more pattern groups in one travel in the predetermined direction of the stage.

### BRIEF DESCRIPTION OF THE DRAWINGS

FIG. 1 is a conceptual diagram illustrating a configuration of a writing apparatus in a first embodiment;

FIG. 2 is a conceptual diagram illustrating a configuration of a shaping aperture array substrate in the first embodiment;

FIG. 3 is a cross-sectional view illustrating a configuration of a blanking aperture array mechanism in the first embodiment;

FIG. 4 is a diagram illustrating an example of a pattern formed on a target object in the first embodiment;

FIG. 5 is a conceptual diagram illustrating an example of a writing operation in the first embodiment;

FIG. 6 is a diagram illustrating an example of a multiple electron beam irradiation region and a writing target pixel in the first embodiment;

FIG. 7 is a flowchart illustrating an example of main steps of a writing method in the first embodiment;

FIG. 8 is a diagram illustrating an example of a dose distribution in the first embodiment;

FIG. 9 is a diagram illustrating an example of each stripe region in the first embodiment;

FIG. 10 is a diagram illustrating an example of a multiple beam writing operation in the first embodiment;

FIG. 11 is a diagram illustrating an example of a dose distribution for a thin pattern of a main chip in the first embodiment;

FIG. 12 is a diagram illustrating an example of a dose distribution for a thick pattern of the main chip in the first embodiment;

FIG. 13 is a diagram illustrating an example of a dose distribution for a thin pattern of a peripheral chip in the first embodiment;

FIG. 14 is a diagram illustrating an example of a dose distribution for a thick pattern of the peripheral chip in the first embodiment;

FIG. 15 is a diagram illustrating an example of a dose distribution of a writing group 2 in the first embodiment;

FIG. 16 is a diagram illustrating an example of a relationship among the proximity effect density, the dose, and the back scattering dose of the writing group 2 in the first embodiment;

FIG. 17 is a diagram illustrating an example of a relationship among the proximity effect density of the writing group 2, the total dose, and a value obtained by adding the ½ incident dose and the back scattering dose in the first embodiment;

FIG. 18 is a diagram illustrating an example of a grid positional relationship in a case where grid positions are not shifted in multiple writing in the first embodiment;

FIG. 19 is a diagram illustrating an example of a grid positional relationship in a case where grid positions are shifted in multiple writing in the first embodiment;

FIG. 20 is a diagram illustrating an example of a relationship among the proximity effect density, the dose, and the back scattering dose of a writing group 2 in a second embodiment;

FIG. 21 is a diagram illustrating an example of a relationship among the proximity effect density of the writing group 2, the total dose, and a value obtained by adding the ½ incident dose and the back scattering dose in the second embodiment;

FIG. 22 is a diagram illustrating an example of a relationship among the proximity effect density, the dose, and the back scattering dose of a writing group 2 in a comparative example of the second embodiment;

FIG. 23 is a diagram illustrating an example of a relationship among the proximity effect density of the writing group 2, the total dose, and a value obtained by adding the ½ incident dose and the back scattering dose in the comparative example of the second embodiment; and

FIG. 24 is a diagram illustrating an example of a pattern formed on a target object in each embodiment.

### DETAILED DESCRIPTION OF THE INVENTION

Hereinafter, embodiments provide a writing method and a writing apparatus capable of reducing an increase in writing time in multiple writing even when there are a plurality of chips with different accuracy.

In the following embodiments, a case of using an electron beam as an example of a charged particle beam will be described. However, the charged particle beam is not limited to the electron beam and may be a beam using charged particles such as an ion beam. The charged particle beam is not limited to a single beam, and may be multiple beams. Hereinafter, a writing apparatus using multiple electron beams using electron beams as an example of the multiple charged particle beams will be described.

### First Embodiment

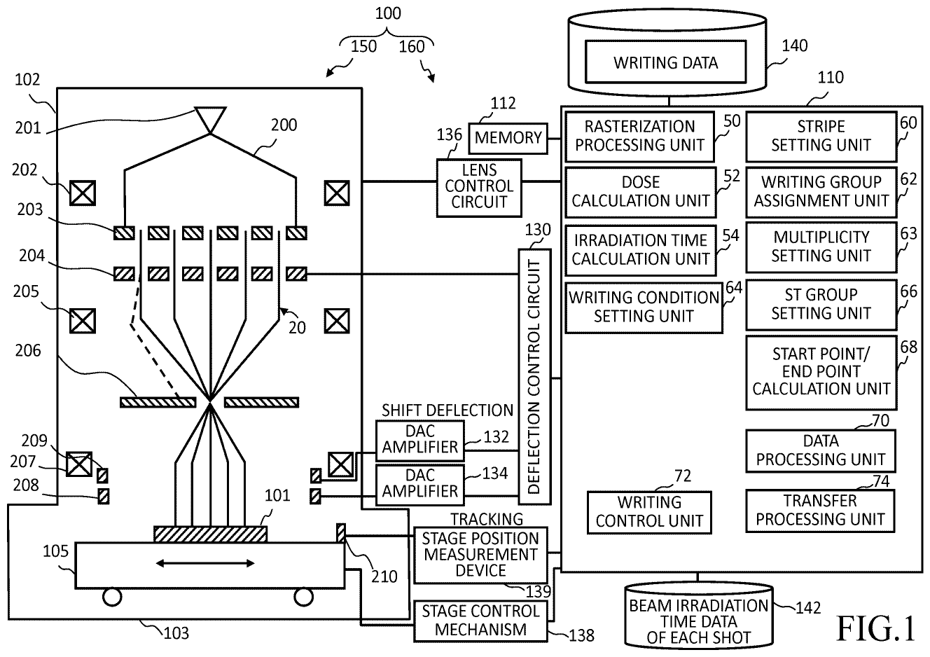

FIG. 1 is a conceptual diagram illustrating a configuration of a writing apparatus in a first embodiment. In FIG. 1, a writing apparatus 100 includes a writing mechanism 150 and a control system circuit 160. The writing apparatus 100 is an example of a multiple charged particle beam writing apparatus and an example of a multiple charged particle beam exposure apparatus. The writing apparatus 100 is an example of a raster beam writing apparatus. The writing mechanism 150 includes an electron optical column 102 (electron beam column) and a writing chamber 103. An electron emission source 201, an illumination lens 202, a shaping aperture array substrate 203, a blanking aperture array mechanism 204, a reduction lens 205, a limiting aperture substrate 206, an objective lens 207, a main deflector 208, and a sub-deflector 209 are disposed in the electron optical column 102.

An XY stage 105 is disposed in the writing chamber 103. On the XY stage 105, a target object 101 such as a mask to be a substrate to be written at the time of writing (at the time of exposure) is disposed. An exposure mask when a semiconductor device is manufactured or a semiconductor substrate (silicon wafer) where the semiconductor device is manufactured is included in the target object 101. In addition, the target object 101 includes mask blanks on which a resist is applied and on which nothing is written. Further, a mirror 210 for measuring a position of the XY stage 105 is disposed on the XY stage 105.

The control system circuit 160 has a control computer 110, a memory 112, a deflection control circuit 130, digital/analog conversion (DAC) amplifier units 132 and 134, a lens control circuit 136, a stage control mechanism 138, a stage position measurement device 139, and storage devices 140 and 142 such as magnetic disk drives. The control computer 110, the memory 112, the deflection control circuit 130, the lens control circuit 136, the stage control mechanism 138, the stage position measurement device 139, and the storage devices 140 and 142 are connected to each other via a bus (not illustrated). The DAC amplifier units 132 and 134 and the blanking aperture array mechanism 204 are connected to the deflection control circuit 130. The sub-deflector 209 is configured by four or more electrodes and is controlled by the deflection control circuit 130 via the DAC amplifier 132 for each electrode. The main deflector 208 is configured by four or more electrodes and is controlled by the deflection control circuit 130 via the DAC amplifier 134 for each electrode. An electronic lens group such as the illumination lens 202, the reduction lens 205, and the objective lens 207 is controlled by the lens control circuit 136. The electronic lens group preferably uses an electromagnetic lens. Alternatively, the electronic lens group may use an electrostatic lens.

The position of the XY stage 105 is controlled by driving of a motor of each shaft (not illustrated) controlled by the stage control mechanism 138. The stage position measurement device 139 receives reflected light from the mirror 210 and measures a position of the XY stage 105 by the principle of a laser interference method.

In the control computer 110, a rasterization processing unit 50, a dose calculation unit 52, a beam irradiation time calculation unit 54, a stripe setting unit 60, a writing group assignment unit 62, a multiplicity setting unit 63, a pattern writing condition setting unit 64, a stripe (ST) group setting unit 66, a start point/end point calculation unit 68, a data processing unit 70, a writing control unit 72, and a transfer processing unit 74 are arranged. Each “unit” such as the rasterization processing unit 50, the dose calculation unit 52, the beam irradiation time calculation unit 54, the stripe setting unit 60, the writing group assignment unit 62, the multiplicity setting unit 63, the pattern writing condition setting unit 64, the stripe group setting unit (ST group setting unit) 66, the start point/end point calculation unit 68, the data processing unit 70, the writing control unit 72, and the transfer processing unit 74 includes a processing circuit. The processing circuit includes an electric circuit, a computer, a processor, a circuit board, a quantum circuit, or a semiconductor device, for example. Each “unit” may use a common processing circuit (the same processing circuit) or may use a different processing circuit (a separate processing circuit) Information input to and output from the rasterization processing unit 50, the dose calculation unit 52, the beam irradiation time calculation unit 54, the stripe setting unit 60, the writing group assignment unit 62, the multiplicity setting unit 63, the pattern writing condition setting unit 64, the stripe group setting unit 66, the start point/end point calculation unit 68, the data processing unit 70, the writing control unit 72, and the transfer processing unit 74 and information during calculation are stored in the memory 112 each time.

The writing operation of the writing apparatus 100 is controlled by the writing control unit 72. In addition, the transfer processing of beam irradiation time data of each shot to the deflection control circuit 130 is controlled by the transfer processing unit 74.

Further, writing data (chip data) is input from the outside of the writing apparatus 100 and stored in the storage device 140. In the chip data, information of a plurality of figure patterns forming a chip pattern is defined. Specifically, for each figure pattern, each vertex coordinate is defined in the order of forming the figure. Alternatively, for example, a figure code, coordinates, a size, and the like are defined for each figure pattern.

Here, in FIG. 1, the configuration necessary for describing the first embodiment is described. The writing apparatus 100 may generally include other necessary configuration.

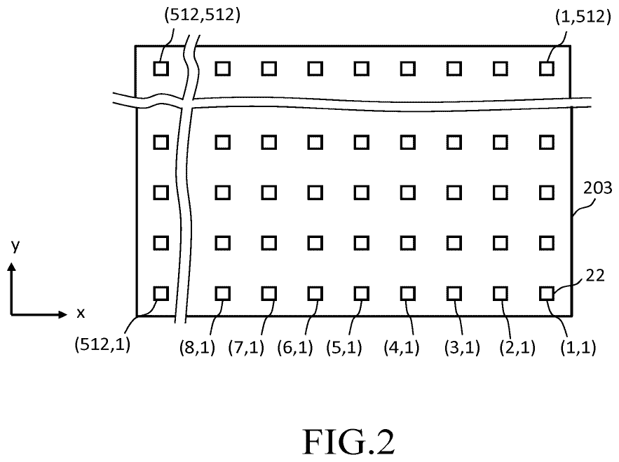

FIG. 2 is a conceptual diagram illustrating a configuration of a shaping aperture array substrate in the first embodiment. In FIG. 2, in the shaping aperture array substrate 203, p×q (p, q≥2) holes (openings) 22 in a width direction (x direction) and a length direction (y direction) are formed in a matrix of rows and columns at a predetermined arrangement pitch. In an example of FIG. 2, a case where 512×512 holes 22 are formed in the width and length directions (x and y directions) is illustrated. The number of the holes 22 is not limited thereto. For example, 32×32 holes 22 may be formed. Each hole 22 is formed of a rectangle having the same dimension and shape. Alternatively, each hole 22 may have a shape of a circle with the same diameter. A part of electron beams 200 passes through the plurality of holes 22, so that multiple electron beams 20 are formed. In other words, the shaping aperture array substrate 203 forms and emits the multiple electron beams 20. The shaping aperture array substrate 203 is an example of an emission source of the multiple electron beams 20 or a multiple beam forming mechanism.

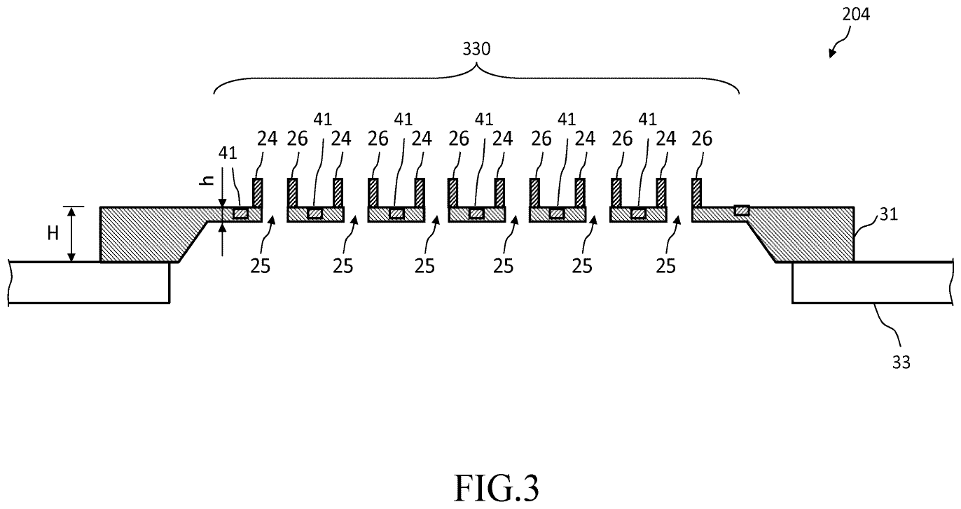

FIG. 3 is a cross-sectional view illustrating a configuration of a blanking aperture array mechanism in the first embodiment. As illustrated in FIG. 3, in the blanking aperture array mechanism 204, the blanking aperture array substrate 31 using a semiconductor substrate made of silicon or the like is arranged on a support base 33. In a membrane region 330 in a center portion having a thickness smaller than that of an outer peripheral portion of the blanking aperture array substrate 31, a passing hole 25 (opening) for passing each beam of the multiple electron beams 20 is formed at a position corresponding to each hole 22 of the shaping aperture array substrate 203 illustrated in FIG. 2. A pair (blanker: blanking deflector) of a control electrode 24 and a counter electrode 26 is disposed at positions facing each other across the corresponding passing hole 25 among the plurality of passing holes 25. In addition, a control circuit 41 (logic circuit) that applies a deflection voltage to the control electrode 24 for each of the passing holes 25 is disposed inside the blanking aperture array substrate 31 in the vicinity of each of the passing holes 25. The counter electrode 26 for each beam is connected to a ground.

An amplifier (an example of a switching circuit) not illustrated in the drawings is disposed in the control circuit 41. As an example of the amplifier, a complementary MOS (CMOS) inverter circuit serving as a switching circuit is disposed. Any one of a low (L) potential (for example, the ground potential) lower than a threshold voltage and a high (H) potential (for example, 1.5 V) equal to or higher than the threshold voltage is applied as a control signal to an input (IN) of the CMOS inverter circuit. In the first embodiment, in a state where the L potential is applied to the input (IN) of the CMOS inverter circuit, control is performed such that the output (OUT) of the CMOS inverter circuit, which is the output of the control circuit 41, becomes the positive potential (Vdd), and the corresponding beam is deflected by the electric field due to the potential difference from the ground potential of the counter electrode 26 and shielded by the limiting aperture substrate 206 to turn off the beam. On the other hand, in a state (active state) where the H potential is applied to the input (IN) of the CMOS inverter circuit, the output (OUT) of the CMOS inverter circuit and the control circuit 41 becomes the ground potential, and the potential difference from the ground potential of the counter electrode 26 disappears and the corresponding beam is not deflected. Therefore, control is performed such that the beam is turned on by passing through the limiting aperture substrate 206. By such deflection, blanking control is performed.

Next, a specific example of the operation of the writing mechanism 150 will be described. The electron beams 200 emitted from the electron emission source 201 (emission source) illuminate the entire shaping aperture array substrate 203 substantially vertically by the illumination lens 202. The plurality of rectangular holes 22 (openings) are formed in the shaping aperture array substrate 203, and the electron beams 200 illuminate a region including all the plurality of holes 22. Each part of the electron beams 200 with which the positions of the plurality of holes 22 are irradiated passes through the plurality of holes 22 of the shaping aperture array substrate 203, so that multiple beams (a plurality of electron beams) 20 having, for example, a rectangular shape are formed. The multiple electron beams 20 pass through the respective corresponding blankers of the blanking aperture array mechanism 204. Such blankers perform blanking control on the beams individually passing through the blankers so that the beams are turned on for a set writing time (beam irradiation time).

The multiple electron beams 20 that have passed through the blanking aperture array mechanism 204 are reduced by the reduction lens 205 and travel toward the center hole formed in the limiting aperture substrate 206. Here, the electron beam deflected by the blanker of the blanking aperture array mechanism 204 is shifted in position from the center hole of the limiting aperture substrate 206 and is shielded by the limiting aperture substrate 206. On the other hand, electron beams not deflected by the blanker of the blanking aperture array mechanism 204 pass through the center hole of the limiting aperture substrate 206 as illustrated in FIG. 1. As described above, the limiting aperture substrate 206 shields each beam deflected to be in the beam OFF state by the blanker of the blanking aperture array mechanism 204. In addition, each beam of one shot is formed by the beam having passed through the limiting aperture substrate 206, formed from beam ON to beam OFF. The multiple electron beams 20 having passed through the limiting aperture substrate 206 are focused by the objective lens 207 to become a pattern image of a desired reduction ratio, the entire multiple electron beams 20 having passed through the limiting aperture substrate 206 are collectively deflected in the same direction by the main deflector 208 and the sub-deflector 209, and the respective irradiation positions of the beams on the target object 101 are irradiated with the multiple electron beams. In addition, for example, when the XY stage 105 is continuously moved, tracking control is performed by the main deflector 208 so that the irradiation position of the beam follows the movement of the XY stage 105. The multiple electron beams 20 to be irradiated at one time are ideally arranged at a pitch obtained by multiplying the arrangement pitch of the plurality of holes 22 of the shaping aperture array substrate 203 by the desired reduction ratio described above.

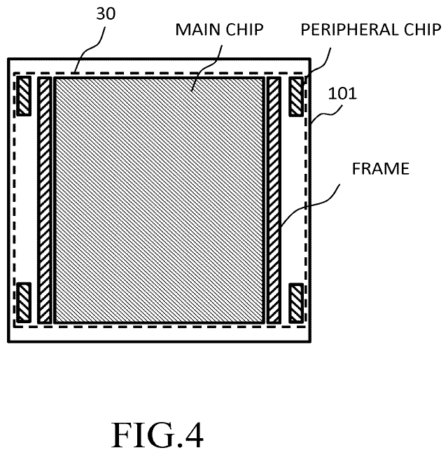

FIG. 4 is a diagram illustrating an example of a pattern formed on a target object in the first embodiment. In FIG. 4, in a target object 101, in addition to a main chip in which a main pattern is assembled in a center portion, peripheral chips in which peripheral patterns arranged around the main chip are assembled may be disposed, or/and frames of frame patterns may be disposed around or inside the main chip. The example of FIG. 4 illustrates a case where the main chip is disposed in the center portion, the frames are disposed on both sides of the main chip, and the peripheral chips are disposed near the four corners of the target object 101 outside the frames.

As described above, the peripheral chips and the frames may have low writing accuracy unlike the main pattern in which high writing accuracy is required. These main chip, peripheral chips, and frames are generally merged and written together. Therefore, a writing region 30 of the target object 101 is a region including the main chip, the peripheral chip, and the frame after the merge processing.

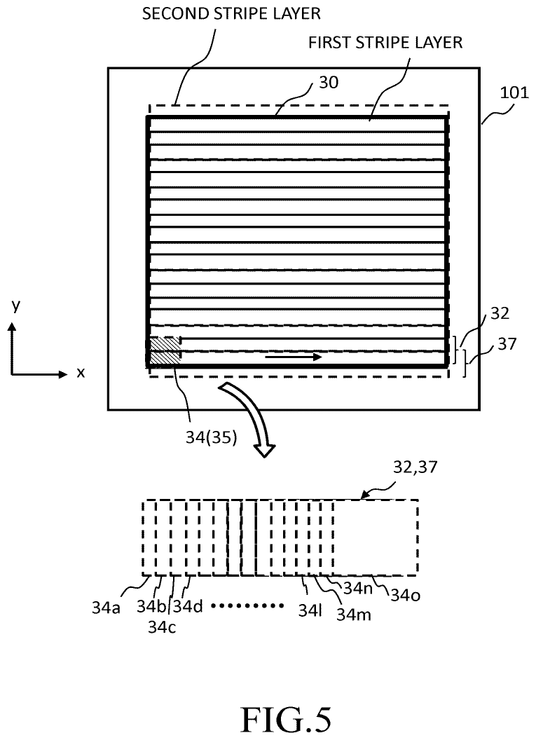

FIG. 5 is a conceptual diagram illustrating an example of a writing operation in the first embodiment. As illustrated in FIG. 5, the writing region 30 (thick line) of the target object 101 is virtually divided into a plurality of strip-like stripe regions 32 (solid lines) with a predetermined width in the y direction, for example. In the example of FIG. 5, the case where the writing region 30 of the target object 101 is divided into the plurality of stripe regions 32 with substantially the same width size as the size of an irradiation region 34 (writing field) in design which can be irradiated with one irradiation of the multiple electron beams 20 in the y direction is illustrated. The size in the x direction of the irradiation region 34 of the multiple electron beams 20 in design can be defined by the number of beams in the x direction×inter-beam pitch in the x direction. The size of the rectangular irradiation region 34 in the y direction can be defined by the number of beams in the y direction×inter-beam pitch in the y direction.

In addition, the main chip often performs multiple writing in order to reduce errors in the position and current amount of each beam of the multiple beams and to improve connection accuracy between patterns at stripe boundaries. Therefore, in the writing region 30 (thick line) of the target object 101, a second stripe layer including a plurality of stripe regions 37 (broken lines) for performing second writing processing of the multiple writing is set in addition to a first stripe layer including the plurality of stripe regions 32 for performing first writing processing of the multiple writing. The plurality of stripe regions 37 are virtually divided in a strip shape with the width size similar to that of the plurality of stripe regions 32, for example, in the y direction. The first stripe layer and the second stripe layer are preferably configured to be shifted in position.

In the multiple writing, multiple pass writing is performed in which the stage moves on the same position a plurality of times. In this case, in the multiple pass writing of the multiplicity N, it is preferable to shift the first stripe layer and the second stripe layer by, for example, a shift amount of a size of 1/N of the width of the stripe region in the y direction. In the example of FIG. 5, a case where two multiple writing is performed is illustrated, and a case where the first stripe layer and the second stripe layer are arranged to be shifted in position in the y direction by a size of ½ of the width of the stripe regions 32 and 37 is illustrated. In addition, it is preferable to alternately write the n-th stripe region 32 of the first stripe layer and the n-th stripe region 37 of the second stripe layer. In addition, the multiple writing is preferably performed by multiple writing (in-pass multiple writing) in which the same position is written with different beams a plurality of times during one stage movement.

It is preferable that the second stripe layer has the stripe region 37 set one more than the first stripe layer at the beginning or the end so as to cover the entire writing region 30.

First, the XY stage 105 is moved and adjusted so that the irradiation region 34 of the multiple electron beams 20 is positioned at the writing start point (for example, the left end or a position on the further left side) of the 0-th stripe region 37 of the second stripe layer overlapping the lower half of the first stripe region 32 of the first stripe layer, and writing of the 0-th stripe region 37 of the second stripe layer is performed. When the 0-th stripe region 37 of the second stripe layer is written, the writing is relatively advanced in the x direction by moving the XY stage 105 in, for example, the −x direction. The XY stage 105 is continuously moved at a constant speed, for example. After completion of writing up to the writing end point (for example, the right end) of the 0-th stripe region 37 of the second stripe layer, the stage position is moved in the −y direction by the size of ½ of the width of the stripe regions 32 and 37.

Next, writing of the first stripe region 32 of the first stripe layer is performed by adjusting the irradiation region 34 of the multiple electron beams 20 so as to be positioned at the writing start point (for example, the left end or a position on the further left side) of the first stripe region 32 of the first stripe layer, and relatively advancing the writing in the x direction by moving the XY stage 105 in, for example, the −x direction. After completion of writing up to the writing end point (for example, the right end) of the first stripe region 32 of the first stripe layer, the stage position is moved in the −y direction by the size of ½ of the width of the stripe regions 32 and 37.

Next, writing of the first stripe region 37 of the second stripe layer is performed by adjusting the irradiation region 34 of the multiple electron beams 20 so as to be positioned at the writing start point (for example, the left end or a position on the further left side) of the first stripe region 37 of the second stripe layer, and relatively advancing the writing in the x direction by moving the XY stage 105 in, for example, the −x direction. After completion of writing up to the writing end point (for example, the right end) of the first stripe region 37 of the second stripe layer, the stage position is moved in the −y direction by the size of ½ of the width of the stripe regions 32 and 37. Thereafter, the above processing is similarly repeated.

The writing start point and the writing end point of each of the stripe regions 32 and 37 will be described later.

In the example described above, the case where the writing of the stripe regions 32 and 37 is advanced in the same direction has been illustrated, but the present invention is not limited thereto. For example, for the stripe region 37 to be written next to the stripe region 32 in which writing has been advanced in the x direction, writing may be relatively performed in the −x direction by moving the XY stage 105 in, for example, the x direction. By performing writing while alternately changing the direction in this manner, the stage moving time can be shortened, and the writing time can be shortened accordingly. In one shot, the multiple electron beams 20 formed by passing through the respective holes 22 of the shaping aperture array substrate 203 form a plurality of shot patterns as many as the respective holes 22 at the maximum at one time.

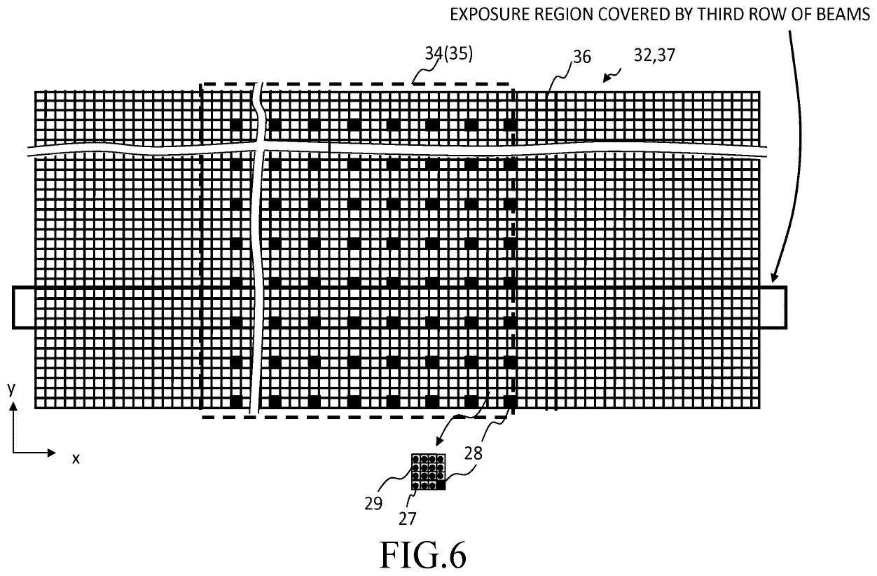

FIG. 6 is a diagram illustrating an example of a multiple electron beam irradiation region and a writing target pixel in the first embodiment. In FIG. 6, the stripe regions 32 and 37 are divided into a plurality of mesh regions of a mesh shape by the beam size of the multiple electron beams 20, for example. Each of such mesh regions is a writing target pixel 36 (irradiation unit region and irradiation position). The size of the writing target pixel 36 is not limited to the beam size, and may be any size regardless of the beam size. For example, the size of the pixel may be 1/n (n is an integer of 1 or more) of the beam size. In the example of FIG. 6, the case where the writing region of the target object 101 is divided into the plurality of stripe regions 32 with substantially the same width size as the size of the irradiation region 34 (writing field) which can be irradiated with one irradiation of the multiple electron beams 20 in the y direction is illustrated. The size of the rectangular irradiation region 34 in the x direction can be defined by the number of beams in the x direction×inter-beam pitch in the x direction. The size of the rectangular irradiation region 34 in the y direction can be defined by the number of beams in the y direction×inter-beam pitch in the y direction. In the example of FIG. 6, for example, 512×512 multiple beams are illustrated to be abbreviated to 8×8 multiple beams. Further, in the irradiation region 34, a plurality of pixels 28 (beam writing positions) which can be irradiated with one shot of the multiple electron beams 20 are illustrated. The pitch between the adjacent pixels 28 is the inter-beam pitch of the multiple beams. One sub-irradiation region 29 (pitch cell region) is configured by a rectangular region surrounded by the size of the inter-beam pitch in the x and y directions. In the example of FIG. 6, the case where each sub-irradiation region 29 is configured by 4×4 pixels is illustrated.

As will be described later, the writing apparatus 100 advances the writing by the raster method. In the raster-type writing method, a writing time is limited by a stage speed. In such a case, a peripheral chip and a frame, which may have low writing accuracy, are written in addition to the main chip in a high-accuracy writing mode in which the stage speed is low in accordance with the main chip, so that the writing time increases.

Therefore, in the first embodiment, the multiplicity is made variable between the main chip and the peripheral chip and the frame. In addition, the peripheral chip and the frame are written with a multiplicity of, for example, ½ of the multiplicity of the main chip. The details will be described below.

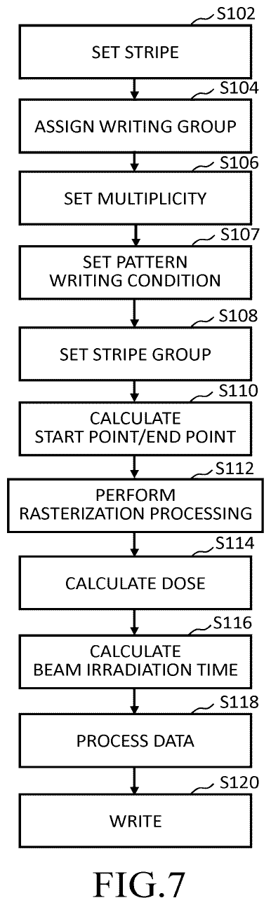

FIG. 7 is a flowchart illustrating an example of main steps of a writing method in the first embodiment. In FIG. 7, the writing method in the first embodiment performs a series of steps including a stripe setting step (S102), a writing group assignment step (S104), a multiplicity setting step (S106), a pattern writing condition setting step (S107), a stripe group setting step (S108), a start point/end point calculation step (S110), a rasterization processing step (S112), a dose calculation step (S114), a beam irradiation time calculation step (S116), a data processing step (S118), and a writing step (S120).

As the stripe setting step (S102), the stripe setting unit 60 sets two or more sets of a plurality of stripe regions 32 and 37, each set including a plurality of stripe regions obtained by dividing the writing region 30 of the target object 101 into a strip shape. As described above, the plurality of stripe regions 32 of the first stripe layer and the plurality of stripe regions 37 of the second stripe layer are set.

The plurality of stripe regions 32 of the first stripe layer and the plurality of stripe regions 37 of the second stripe layer are shifted in position in the y direction by a size of ½ of the stripe region width, for example, as illustrated in FIG. 5.

Alternatively, the plurality of stripe regions 32 of the first stripe layer and the plurality of stripe regions 37 of the second stripe layer are preferably shifted in position in, for example, the x and y directions with a size smaller than the size of the pixel 36.

Alternatively, as illustrated in FIG. 5, for example, the plurality of stripe regions 32 of the first stripe layer and the plurality of stripe regions 37 of the second stripe layer may be shifted in the y direction by a size of ½ of the stripe region width, and may be shifted in position in the x and y directions with a size smaller than the size of the pixel 36.

As the writing group assignment step (S104), the writing group assignment unit 62 assigns a plurality of patterns to be written to any of a plurality of pattern groups. Here, as the plurality of pattern groups, a pattern group belonging to the main chip is assigned to a writing group 1, and a pattern group belonging to the peripheral pattern and the frame is assigned to a writing group 2. Here, description is given using two patterns (writing groups 1 and 2), but the present invention is not limited thereto. There may be three or more pattern groups (writing groups).

As the multiplicity setting step (S106), the multiplicity setting unit 63 sets the multiplicity of multiple writing to different values between pattern groups for each writing group of the plurality of assigned writing groups (pattern groups). In other words, the multiplicity setting unit 63 sets the multiplicity of multiple writing to values different from those of other writing groups for each writing group of the plurality of assigned writing groups (pattern groups). For example, the multiplicity of multiple writing is set to each preset value. Alternatively, the multiplicity of multiple writing is variably set to an arbitrary value. When three or more writing groups are used, at least one pattern group less than two or more writing groups of the three or more writing groups is set to a lower (less) multiplicity than the remaining writing groups of the two or more pattern groups. In the case of the two writing groups 1 and 2, one of the plurality of writing groups is set to a lower (less) multiplicity than the other. Here, the multiplicity of the writing group 2 which may have low writing accuracy is set to ½ of the multiplicity of the writing group 1 which requires high writing accuracy. For example, the multiplicity N of the writing group 1 is set to 2, and the multiplicity N of the writing group 2 is set to 1.Therefore, the writing group 1 performs 2 multiple pass writing, and the writing group 2 performs 1 pass writing. Note that multiple writing may be performed in the same pass. Here, a case where multiple writing is not performed in the same pass will be described.

As the pattern writing condition setting step (S107), the pattern writing condition setting unit 64 sets base doses of the beam D_{base1} and a back scattering coefficient η₁ of the writing group 1. Similarly, base doses of the beam D_{base2} (and a back scattering coefficient η₂) of the writing group 2 are set.

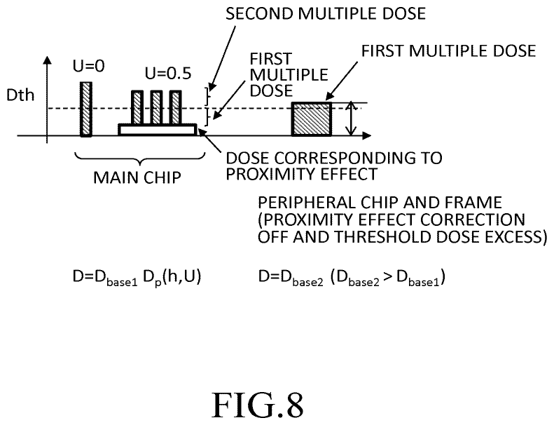

FIG. 8 is a diagram illustrating an example of a dose distribution in the first embodiment. The base doses of the beam D_{base1} of the writing group 1 are set to, for example, a threshold dose Dth that is a resolution threshold of the resist. The base doses of the beam D_{base2} of the writing group 2 are larger than the base doses of the beam D_{base1} of the writing group 1. For example, the base doses of the beam D_{base2} are set to a value (larger value) exceeding the threshold dose Dth. For example, the base doses of the beam D_{base2} are set to 1.25 times the threshold dose Dth.

For example, in a case of the back scattering coefficient η=0.5, the dose modulation of 2.0 times the threshold dose Dth is required only by the proximity effect correction. In consideration of other modulation amounts, the maximum dose is estimated to be 2.5 times the threshold dose Dth. Therefore, in the N multiple writing, the maximum dose is set to Dth×2.5/N per writing processing. Therefore, in two multiple writing, it is preferable to set the maximum dose to 1.25 times the threshold dose Dth per writing. Therefore, in the writing group 2, the base doses of the beam D_{base2} of the writing group 2 are set to, for example, 1.25 times the threshold dose Dth so as to exceed the threshold dose Dth in one writing even when the proximity effect correction is not performed. As a result, in the writing group 1, two multiple writing are required, whereas in the writing group 2, only one writing may be performed.

As the stripe group setting step (S108), the stripe group setting unit 66 sets, as the stripe group 1, a pattern of a main chip of the writing group 1, a pattern of a peripheral chip of the writing group 2, and/or a pattern of a frame arranged in the stripe region 32 for each stripe region 32 of the first stripe layer on which the first writing is performed. In addition, the stripe group setting unit 66 sets, as the stripe group 2, a pattern of a main chip of the writing group 1 arranged in the stripe region 37 for each stripe region 37 of the second stripe layer on which the second writing is performed.

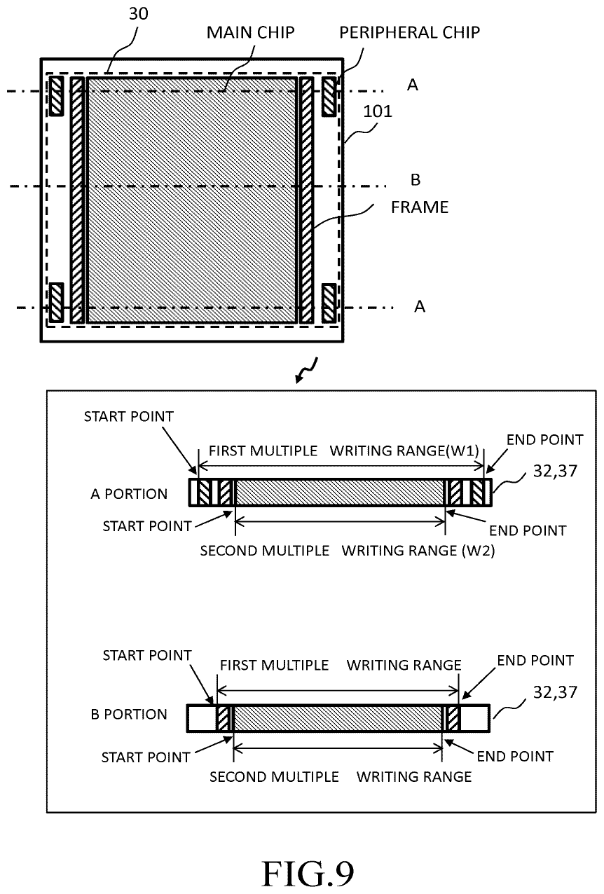

FIG. 9 is a diagram illustrating an example of each stripe region in the first embodiment. In the stripe region 32 of the first stripe layer located in an A portion of FIG. 9, the pattern of the peripheral chip, the pattern of the frame, the pattern of the main chip, the pattern of the frame, and the pattern of the peripheral chip are arranged as the stripe group 1 from the left side. On the other hand, in the stripe region 37 of the second stripe layer located in the A portion of FIG. 9, only the pattern of the main chip is arranged as the stripe group 2.

In the stripe region 32 of the first stripe layer located in a B portion of FIG. 9, the pattern of the frame, the pattern of the main chip, and the pattern of the frame are arranged as the stripe group 1 from the left side. On the other hand, in the stripe region 37 of the second stripe layer located in the B portion of FIG. 9, only the pattern of the main chip is arranged as the stripe group 2.

As the start point/end point calculation step (S110), the start point/end point calculation unit 68 calculates a writing start point and a writing end point of the stripe group 1 for each stripe region 32 of the first stripe layer. Similarly, the start point/end point calculation unit 68 calculates a writing start point and a writing end point of the stripe group 2 for each stripe region 37 of the second stripe layer. Here, a case where the writing direction is the x direction will be described. When the writing direction is the −x direction, the start point and the end point are reversed.

In the stripe region 32 of the first stripe layer located in the A portion of FIG. 9, since the pattern of the peripheral chip of the stripe group 1 is first arranged, the start point is the left end of the peripheral chip on the left side. Thereafter, the pattern of the frame, the pattern of the main chip, and the pattern of the frame are continued, and the pattern of the peripheral chip is finally arranged. Therefore, the end point is the right end of the right peripheral chip.

On the other hand, in the stripe region 37 of the second stripe layer located in the A portion of FIG. 9, since only the pattern of the main chip of the stripe group 2 is arranged, the start point is the left end of the main chip. The end point is the right end of the main chip.

In the stripe region 32 of the first stripe layer located in the B portion of FIG. 9, since the pattern of the frame of the stripe group 1 is first arranged, the start point is the left end of the left frame. Thereafter, the pattern of the main chip is continued, and the pattern of the frame is finally arranged. Therefore, the end point is the right end of the right frame.

On the other hand, in the stripe region 37 of the second stripe layer located in the B portion of FIG. 9, since only the pattern of the main chip of the stripe group 2 is arranged, the start point is the left end of the main chip. The end point is the right end of the main chip.

As the rasterization processing step (S112), the rasterization processing unit 50 reads chip pattern data (writing data) from the storage device 140 and performs rasterization processing. Specifically, the pattern density ρ(x) (pattern area density) of the figure pattern arranged in the pixel is calculated for each pixel 36. For example, it is preferable to perform rasterization processing for each stripe region 32. Here, the rasterization processing is performed for each stripe region 32 of the first stripe layer and each stripe region 37 of the second stripe layer.

As the dose calculation step (S114), the dose calculation unit 52 calculates a dose to be incident on the pixel for each pixel 36. Specifically, the following operation is performed.

In the writing group 1, the dose D may be calculated as, for example, a value obtained by multiplying the preset base doses of the beam D_{base1} by a proximity effect-corrected dose Dp and a pattern area density ρ. The proximity effect-corrected dose Dp is given as a relative value normalized with the base doses of the beam D_{base1} as 1. As described above, the dose D is preferably obtained in proportion to the area density of the pattern calculated for each pixel 36. For the proximity effect-corrected dose Dp, the writing region (here, for example, the stripe regions 32 and 37) is virtually divided into a plurality of proximity mesh regions (proximity effect correction calculation mesh regions) in a mesh shape with a predetermined size. The size of the proximity mesh region is preferably set to about 1/10 of a range of influence of a proximity effect, for example, about 1 μm. The writing data is read from the storage device 140, and the pattern density ρ′ (pattern area density) of the pattern arranged in the proximity mesh region is calculated for each proximity mesh region.

Next, the proximity effect-corrected dose Dp for correcting the proximity effect is calculated for each proximity mesh region. Here, the size of the mesh region for calculating the proximity effect-corrected dose Dp does not need to be the same as the size of the mesh region for calculating the pattern area density ρ. In addition, a correction model of the proximity effect-corrected dose Dp and a calculation method thereof may be similar to the method used in the conventional single beam writing method. A dose map in which dose data for each pixel 36 is defined is created.

The proximity effect density U at this time can be obtained by performing convolution integration of a distribution function of the proximity effect, for example, a distribution function of a Gaussian function or the like on the pattern density ρ′.

When multiple writing is performed, a dose map is created for each writing processing of each number of times of multiplexing. In other words, a dose map is created for each stripe layer. The created dose map is stored in the storage device 142. The dose of the writing processing of each multiplexing number of N multiplexing is 1/N of the dose D calculated for each pixel.

In the writing group 2, since the proximity effect correction is not performed, the dose D may be calculated as a value obtained by multiplying the preset base doses of the beam D_{base2} by the pattern area density ρ. In the edge portion of the pattern, since the pattern area density ρ is smaller than 1, the dose falls below the threshold dose Dth. However, the pattern included in the writing group 2 has a large dimension, and many pixels whose doses exceed the threshold dose Dth are present in the entire pattern, so that resolution can be achieved.

As the beam irradiation time calculation step (S116), the beam irradiation time calculation unit 54 calculates a beam irradiation time t of the electron beam for causing the calculated dose D to be incident on the pixel 36 for each pixel 36 of each of the stripe regions 32 and 37. The beam irradiation time t can be calculated by dividing the dose D by the current density J. As a result, a beam irradiation time map in which beam irradiation time data for each pixel 36 is defined is created. The created beam irradiation time map is stored in the storage device 142.

As the data processing step (S118), the data processing unit 70 performs data processing so as to rearrange the beam irradiation time data in shot order. The beam irradiation time data is stored in the storage device 142.

Then, the transfer processing unit 74 transfers the beam irradiation time data to the deflection control circuit 130 in shot order.

As the writing step (S120), under the control of the writing control unit 72, the writing mechanism 150 write the plurality of patterns on the target object 101 with the multiplicity set for each writing group using the multiple electron beams 20 (charged particle beams) by performing
processing of writing each pattern of two or more writing groups among the plurality of writing groups in one travel of the XY stage 105 on which the target object 101 is placed, for example, in the −x direction (predetermined direction) and
processing of writing no pattern of at least one writing group less than two or more pattern groups among the two or more writing groups and writing a pattern of the remaining writing group of the two or more writing groups in one travel of the XY stage 105, for example, in the −x direction (predetermined direction). When there are two writing groups, the following operation is performed. The writing mechanism 150 performs processing of writing each pattern of a plurality of writing groups 1 and 2 in one travel of the XY stage 105 on which the target object 101 is placed, for example, in the −x direction (predetermined direction) and processing of writing a pattern of one writing group 1 of the plurality of writing groups 1 and 2 and not writing a pattern of the other writing group 2 in one travel of the XY stage 105, for example, in the −x direction (predetermined direction), thereby writing a plurality of patterns on the target object 101 with the multiplicity set for each writing group using the multiple electron beams 20 (charged particle beams). When the plurality of stripe regions 32 of the first stripe layer (one set) are written, each pattern of the plurality of writing groups 1 and 2 is written, and when the plurality of stripe regions 37 of the second stripe layer (the other set) are written, a pattern of one writing group 1 of the plurality of writing groups 1 and 2is written, and a pattern of the other writing group 2 is not written.

In such a case, in each of the stripe regions 32 and 37, writing is started from the start point calculated in the start point/end point calculation step (S110), and writing is ended at the calculated end point. In the A portion of FIG. 9, when the stripe region 32 of the first stripe layer is written, writing is started with the left end of the left peripheral chip as a start point, and writing is ended with the right end of the right peripheral chip as an end point.

On the other hand, in the A portion of FIG. 9, when the stripe region 37 of the second stripe layer is written, writing is started with the left end of the main chip as a start point, and writing is ended with the right end of the main chip as an end point.

In addition, in the B portion of FIG. 9, when the stripe region 32 of the first stripe layer is written, writing is started with the left end of the left frame as a start point, and writing is ended with the right end of the right frame as an end point.

On the other hand, in the B portion of FIG. 9, when the stripe region 37 of the second stripe layer is written, writing is started with the left end of the main chip as a start point, and writing is ended with the right end of the main chip as an end point.

Therefore, when each stripe region 37 of the second stripe layer is written, the length of the writing range in the stripe region can be shorter as compared with when each stripe region 32 of the first stripe layer is written. In other words, the stage travel distance can be shortened. Since the length of the writing range in the stripe region is short, the writing time can be shortened when each stripe region 37 of the second stripe layer is written. The X coordinates of the writing start point and the writing end point of each stripe of the first stripe layer and each stripe of the second stripe layer are often different from each other. For this reason, when each stripe of the second stripe layer is written after completion of writing of each stripe of the first stripe layer, the X coordinates of the writing position when writing of a certain stripe is completed and the writing start position of the stripe to be written next are often the same, and the stage movement distance in the X direction between stripe writing can be reduced, which is preferable. As described above, the n-th stripe region 32 of the first stripe layer and the n-th stripe region 37 of the second stripe layer may be alternately written.

For example, in the A portion of FIG. 9, the length of the writing range in the stripe region 32 when the stripe region 32 of the first stripe layer is written is set to W1, and the length of the writing range in the stripe region 37 when the stripe region 37 of the second stripe layer is written is set to W2. Here, for simple description, each of the stripe regions 32 and 37 has a configuration of the A portion of FIG. 9. In this case, when the stage speed S is used, when the stripe region 32 of the first stripe layer is written, the writing time is W1/S. When the stripe region 37 of the second stripe layer is written, the writing time is W2/S. The stage speed S is preferably set to a speed when a shot cycle is set with D_{base2} as the maximum beam irradiation time, for example.

Therefore, when the number of stripes of each stripe layer is set to n, the writing time Ts1 can be defined by the following Formula (1).

$$Ts 1 = ( W 1 / S + W 2 / S ) n \qquad ( 1 )$$

On the other hand, when the peripheral chip and the main chip are written with the same number of times of multiplexing as in the related art, the writing time Ts2 can be defined by the following Formula (2).

$$Ts 2 = ( W 1 / S + W 1 / S ) n \qquad ( 2 )$$

Since W1>W2 is satisfied, Ts1<Ts2 can be satisfied. Therefore, the writing time can be shortened.

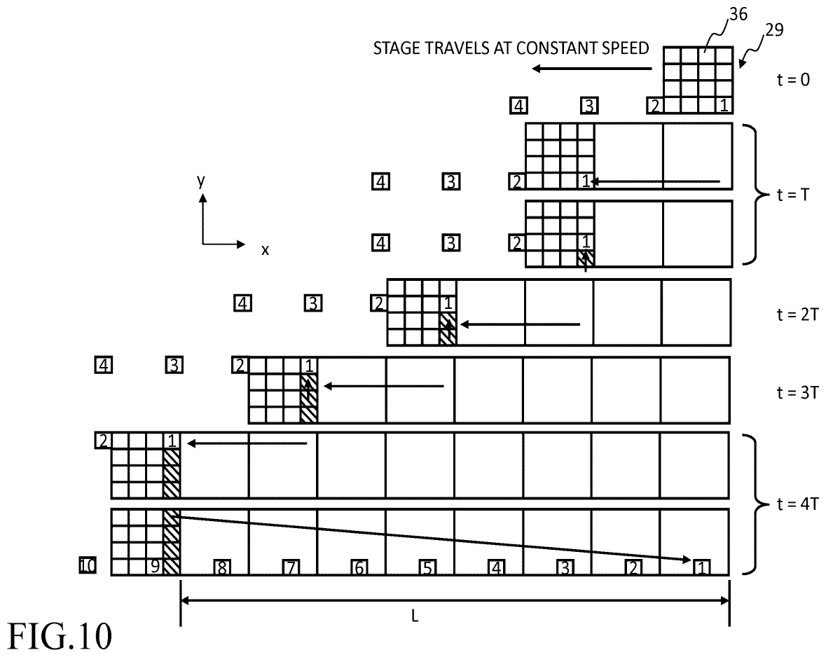

FIG. 10 is a diagram illustrating an example of a multiple beam writing operation in the first embodiment. In the example of FIG. 10, a case where the inside of each sub-irradiation region 29 is written with four different beams is illustrated. In addition, the example of FIG. 10 illustrates a writing operation in which the XY stage 105 continuously moves at a speed of moving by the distance L corresponding to the 8 beam pitches while a ¼ (1/the number of beams used for irradiation) region in each sub-irradiation region 29 is written. In the writing operation illustrated in the example of FIG. 10, for example, four different pixels in the same sub-irradiation region 29 are written (exposed) by four shots of the multiple beams 20 in the shot cycle T while sequentially shifting the irradiation positions (pixels 36) by the sub-deflector 209 while the XY stage 105 moves by the distance L corresponding to the 8 beam pitches. During writing (exposing) of the four pixels, the irradiation region 34 is caused to follow the movement of the XY stage 105 by deflecting the entire multiple beams 20 collectively by the main deflector 208, such that a relative position with the target object 101 is not shifted due to the movement of the XY stage 105. In other words, tracking control is performed. When one tracking cycle ends, tracking is reset, and the tracking position returns to the previous tracking start position. Since the writing of the first pixel column from the right side of each sub-irradiation region 29 is completed, the sub-deflector 209 first performs deflection so as to adjust (shift) the beam writing position so as to write the second pixel column from the right, for example, which has not yet been written, of each sub-irradiation region 29 in a next tracking cycle after the tracking is reset. By repeating such an operation during writing of the stripe region 32, the positions of the irradiation regions 34 of the multiple beams 20 sequentially move as illustrated in irradiation regions 34a, 34b, 34c, . . . , and 34o illustrated in the lower diagram of FIG. 5, and writing is performed. In this manner, raster beam writing is performed such that each pixel 36 can be sequentially irradiated with a beam regardless of the presence or absence of a pattern.

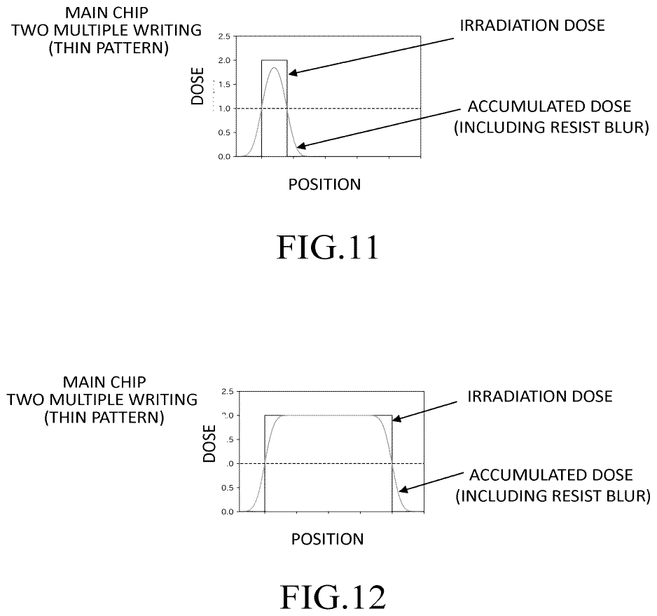

FIG. 11 is a diagram illustrating an example of a dose distribution for a thin pattern of a main chip in the first embodiment.

FIG. 12 is a diagram illustrating an example of a dose distribution for a thick pattern of the main chip in the first embodiment.

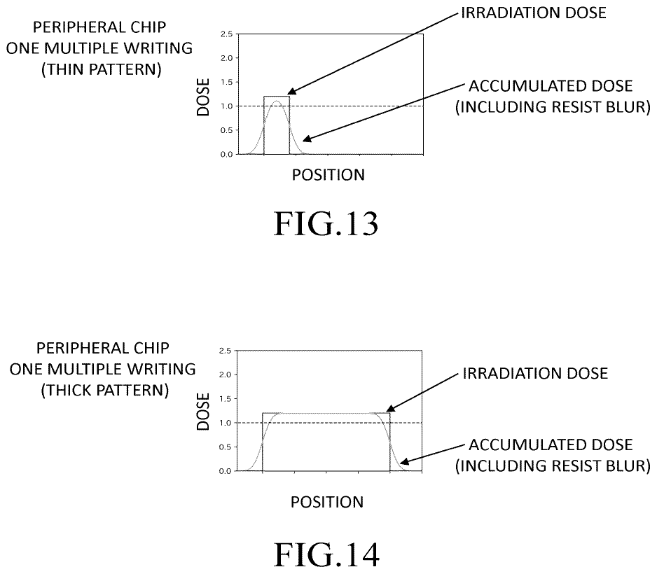

FIG. 13 is a diagram illustrating an example of a dose distribution for a thin pattern of a peripheral chip in the first embodiment.

FIG. 14 is a diagram illustrating an example of a dose distribution for a thick pattern of the peripheral chip in the first embodiment.

As illustrated in FIGS. 11 and 12, when the main chip is written, the target pixel 36 is irradiated with a dose that is about twice the threshold dose by 2 multiple writing. Therefore, in both the thin pattern and the thick pattern, a pattern having a line width of a design dimension is obtained at the threshold dose.

On the other hand, as illustrated in FIGS. 13 and 14, when the peripheral chip is written, the incident dose is slightly larger than the threshold dose, and thus, in the accumulated dose in the resist, the width exceeding the threshold dose is smaller than the design dimension. In thin patterns, it can also happen that they are not resolved in some cases. However, in peripheral chips and frames, a pattern that is too thin to be resolved is not usually used, and thus, it is difficult for non-resolving to occur.

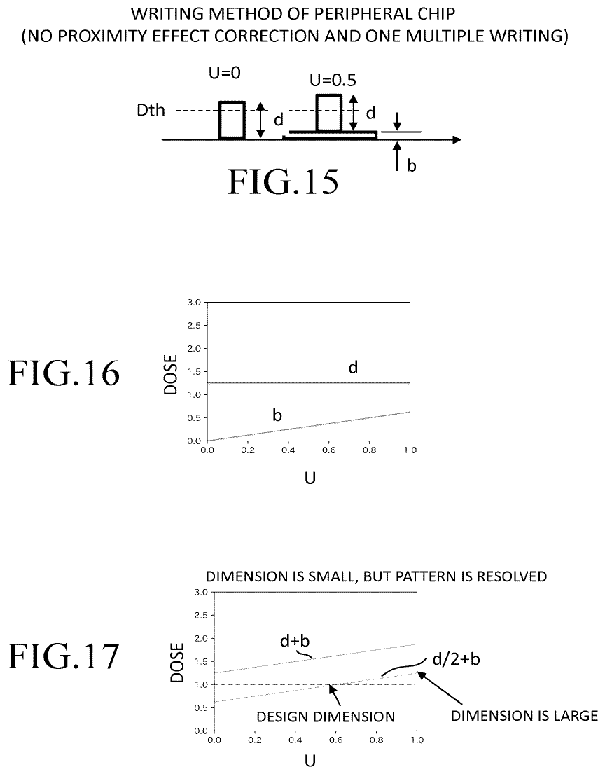

FIG. 15 is a diagram illustrating an example of a dose distribution of the writing group 2 in the first embodiment.

FIG. 16 is a diagram illustrating an example of a relationship among the proximity effect density, the dose, and the back scattering dose of the writing group 2in the first embodiment.

FIG. 17 is a diagram illustrating an example of a relationship among the proximity effect density of the writing group 2, the total dose, and a value obtained by adding the ½ incident dose and the back scattering dose in the first embodiment.

As illustrated in FIGS. 15 and 16, the incident dose of the writing group 2 in the first embodiment is constant at, for example, 1.25 times the threshold dose Dth regardless of the proximity effect density U. In the case of the proximity effect density U=0, no accumulation of the back scattering dose occurs. On the other hand, the accumulation of the back scattering dose b increases as the proximity effect density U increases. Therefore, as illustrated in FIG. 17, in a case of the proximity effect density U=0, accumulation of the back scattering dose does not occur, and thus the incident dose d becomes the total dose. On the other hand, for example, in a case of the proximity effect density U=0.5 (50%), the back scattering dose b is accumulated. Therefore, the sum of the incident dose d and the back scattering dose b is the total dose. Therefore, as the proximity effect density U increases, the total dose (d+b) increases. However, the incident dose of the writing group 2 in the first embodiment is constant at a value of the dose Dth×1.25. As illustrated in FIG. 12, in the thick pattern, the accumulation dose becomes ½ of the irradiation dose at the end position of the design pattern due to the resist blur. Therefore, for the total dose at the end position of the design pattern, the sum (d/2+b) of ½ of the incident dose d and the back scattering dose b becomes the threshold dose Dth. From FIG. 16, (d/2+b) in the writing group 2 changes depending on the proximity effect density U as illustrated in FIG. 17. Therefore, the line width of the pattern to be resolved changes depending on the proximity effect density U. As illustrated in FIG. 17, when the proximity effect density U is small, the accumulated dose at the end position of the design pattern is smaller than the threshold dose. That is, the line width of the pattern is smaller than the designed dimension. In addition, at a certain proximity effect density U, the accumulated dose at the end position of the design pattern coincides with the threshold dose, and the line width of the pattern coincides with the design dimension. When the proximity effect density U further increases, the accumulated dose at the end position of the design pattern becomes larger than the threshold dose, and the line width of the pattern becomes larger than the design dimension as U increases. As described above, the pattern dimension to be written changes according to the proximity effect density U, but there is no problem because the writing accuracy of the pattern of the writing group 2 may be low.

In the writing group 1, although not illustrated, the incident dose d is adjusted by the proximity effect-corrected dose Dp such that the sum (d/2+b) of ½ of the incident dose d and the back scattering dose b becomes the threshold dose Dth. Therefore, since the pattern dimension to be written does not change according to the proximity effect density U, the writing accuracy of the pattern of the writing group 1 can be increased.

Next, the interval between the grids 27 for forming the pixels 36 will be described. The grid 27 is an irradiation position at which each beam is irradiated. The first embodiment is also preferable to configure such that the grid width indicating the width between the grids 27 is variably controlled for each writing group by writing a plurality of patterns in accordance with the multiplicity.

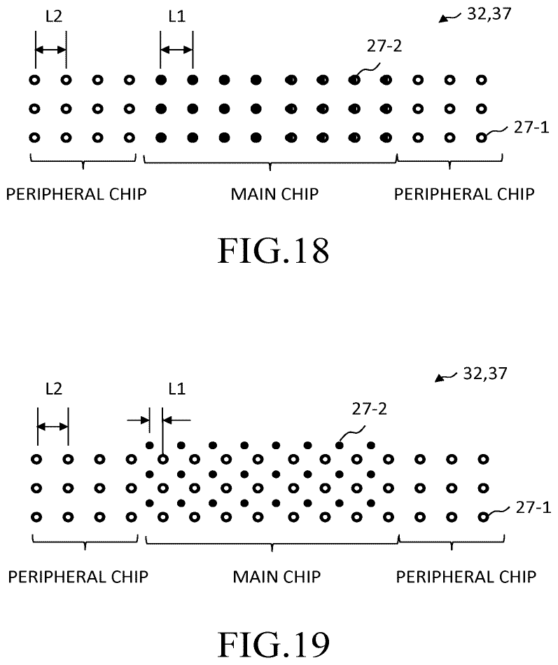

FIG. 18 is a diagram illustrating an example of a grid positional relationship in a case where grid positions are not shifted in multiple writing in the first embodiment.

FIG. 19 is a diagram illustrating an example of a grid positional relationship in a case where grid positions are shifted in multiple writing in the first embodiment.

The example of FIG. 18 illustrates a case where the positional shift is not performed with a size less than the grid width indicating the width between the grids between a plurality of grids 27-1 in each stripe region 32 for the first writing of the multiple writing and a plurality of grids 27-2 in each stripe region 37 for the second writing. For example, even when the position is shifted in the y direction by a size of ½ of the stripe region width, the position of the grid is not shifted between pixels overlapping each other. In this case, the grid width L1 in the region of the main chip and the grid width L2 in the region of the peripheral chip have the same size.

On the other hand, in the example of FIG. 19, a case is illustrated in which the position is shifted with a size smaller than the grid width indicating the width between the grids between the plurality of grids 27-1 in each stripe region 32 for the first writing of the multiple writing and the plurality of grids 27-2 in each stripe region 37 for the second writing. In other words, a case where multiple writing is performed by shifting the positions of a plurality of grids on the target object 101, which are irradiation positions irradiated with each beam of the multiple electron beams 20, with a size less than the grid width in at least one writing processing of a plurality of writing processing in which one writing is performed among multiple writing is illustrated. In the example of FIG. 19, a case where the position is shifted in the x and y directions with a size of ½ of the grid width is illustrated. In this case, the grid width L1 in the region of the main chip and the grid width L2 in the region of the peripheral chip can be set to different sizes. By controlling the shift amount, the grid width can be made variable between the main chip and the peripheral chip. When three or more writing groups are used, at least one pattern group less than two or more writing groups among the three or more writing groups is written with a larger grid width than the remaining writing groups of the two or more pattern groups. The example of FIG. 19 illustrates a case where two writing groups are used, and as a result of multiple writing, a writing group 2, which is one of the plurality of writing groups, is written with a larger grid width than a writing group 1, which is the other writing group. In the example of FIG. 19, the scanning of the second pass is performed in the region scanned with the stripe of the first pass, so that the interval of the grids changes in the region scanned with the stripe of the first pass.

As described above, according to the first embodiment, the range of the stripe region 37 (an example of the writing region) to be actually written can be narrowed in the second writing processing in which the pattern of the writing group 2 having a low multiplicity is not written among the plurality of writing processing of multiple writing, for example. For this reason, since there is no writing time for a region out of the range of the stripe region 37 to be actually written, the entire writing time can be shortened. Therefore, even when there are a plurality of chips with different accuracy, an increase in the writing time in multiple writing can be reduced.

### Second Embodiment

In the first embodiment, the configuration in which the proximity effect correction is not performed for the dose of the writing group 2 has been described, but the present invention is not limited thereto. In a second embodiment, a configuration for performing proximity effect correction weaker than the pattern of the writing group 1 for the dose of the writing group 2 will be described. The configuration of the writing apparatus in the first embodiment is similar to that in FIG. 1. Further, a flowchart illustrating a main configuration of a writing method in the second embodiment is similar to that of FIG. 7. Contents other than points specifically described below are similar to those in the first embodiment.

The contents of each step of the stripe setting step (S102), the writing group assignment step (S104), and the multiplicity setting step (S106) are similar to those in the first embodiment.

As the pattern writing condition setting step (S107), the pattern writing condition setting unit 64 sets base doses of the beam D_{base1} and a back scattering coefficient η₁ of the writing group 1. Similarly, base doses of the beam D_{base2} and a back scattering coefficient η₂ of the writing group 2 are set. The base doses of the beam D_{base1}, the back scattering coefficient η₁, and the base doses of the beam D_{base2} of the writing group 2 are similar to those in the first embodiment. The back scattering coefficient η₂ is set to a value smaller than the back scattering coefficient η₁.

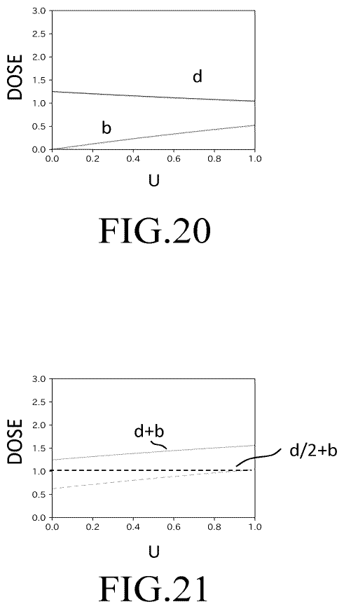

FIG. 20 is a diagram illustrating an example of a relationship among the proximity effect density, the dose, and the back scattering dose of the writing group 2 in the second embodiment.

FIG. 21 is a diagram illustrating an example of a relationship among the proximity effect density of the writing group 2, the total dose, and a value obtained by adding the ½ incident dose and the back scattering dose in the second embodiment.

In FIGS. 20 and 21, η₂ smaller than the back scattering coefficient η₁=0.5 for adjusting the 50% dose to the threshold dose is set. For example, η₂=0.1 is set. As illustrated in FIG. 20, the incident dose d of the writing group 2 in the second embodiment is changed according to the proximity effect density U since weak proximity effect correction is performed. In the example of FIG. 20, as described above, in a case of the proximity effect density U=0, no accumulation of the back scattering dose occurs. On the other hand, the accumulation of the back scattering dose b increases as the proximity effect density U increases. Therefore, as illustrated in FIG. 20, in a case of the proximity effect density U=0, accumulation of the back scattering dose does not occur, and thus the incident dose d becomes the total dose as illustrated in FIG. 21. On the other hand, for example, in a case of the proximity effect density U=1, the back scattering dose b is accumulated. Therefore, the sum of the incident dose d and the back scattering dose b is the total dose. Therefore, as the proximity effect density U increases, the total dose (d+b) increases.

In the second embodiment, regardless of the proximity effect density U, the accumulated dose at the end of the design pattern is not controlled so that the sum (d/2+b) of ½ the incident dose d and the back scattering dose b becomes the threshold dose Dth, but a weaker proximity effect correction is applied by using η₂ which is smaller than η₁ of the main chip. Therefore, the sum (d/2+b) of ½ of the incident dose d and the back scattering dose b increases according to the proximity effect density U. The example of FIG. 21 illustrates a case where the sum (d/2+b) of ½ of the incident dose d and the back scattering dose b becomes the threshold dose Dth at U=1. By performing such weak proximity effect correction, the sum (d/2+b) of ½ of the incident dose d and the back scattering dose b, that is, the slope of the accumulated dose at the end of the design pattern can be made smaller than that in the case of FIG. 17 of the first embodiment. In other words, the variation in the line width of the pattern due to the difference in the proximity effect density U can be reduced.

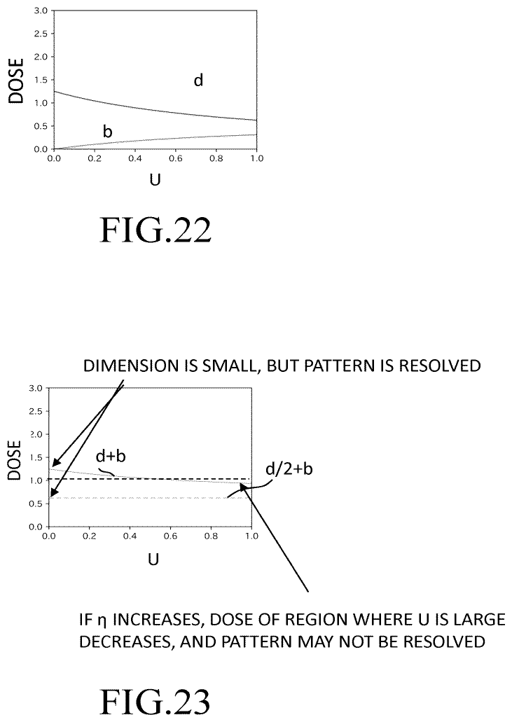

FIG. 22 is a diagram illustrating an example of a relationship among the proximity effect density, the dose, and the back scattering dose of the writing group 2 in a comparative example of the second embodiment.

FIG. 23 is a diagram illustrating an example of a relationship among the proximity effect density of the writing group 2, the total dose, and a value obtained by adding the ½ incident dose and the back scattering dose in the comparative example of the second embodiment. The comparative example illustrates a case where the back scattering coefficient η₂ is set to a large value. For example, the back scattering coefficient 0.5 for adjusting a 50% dose to a threshold dose is applied to the writing groups 1 and 2 and set to η₂=η₁=0.5.

For the writing group 2, the base doses of the beam D_{base2} are set to a value smaller than 1 so that the maximum dose is 1.25 times the previously set threshold dose Dth. In a case where the incident dose d in the case of U=0 where the dose is maximized by proximity effect correction is fixed to the threshold dose Dth×1.25, when η₂ is increased to, for example, 0.5, the incident dose d is adjusted by proximity effect correction such that the sum (d/2+b) of ½ of the incident dose d and the back scattering dose b, that is, the total dose at the end position of the design pattern matches the dose of ½ of the threshold dose Dth×1.25 as illustrated in FIG. 23. Therefore, as illustrated in FIG. 22, the incident dose d greatly decreases as the proximity effect density U increases. Therefore, for example, when the proximity effect density U is around 1, the total dose d+b inside the design pattern may become smaller than the threshold dose Dth, and the writing pattern may not be resolved at all. Therefore, it can be seen that the back scattering coefficient η₂ of the writing group 2 needs to be set to a value smaller than the back scattering coefficient matching the threshold dose.

The contents of each step of the stripe group setting step (S108), the start point/end point calculation step (S110), and the rasterization processing step (S112) are similar to those in the first embodiment.

As the dose calculation step (S114), the dose calculation unit 52 calculates a dose to be incident on the pixel for each pixel 36. A method of calculating the dose of the writing group 1 is similar to that of the first embodiment.

In the second embodiment, the dose D for the writing group 2 is also calculated as, for example, a value obtained by multiplying preset base doses of the beam D_{base2} by a proximity effect-corrected dose Dp and a pattern area density ρ. The proximity effect-corrected dose Dp is given as a relative value normalized with the base doses of the beam D_{base2} as 1. For the proximity effect-corrected dose Dp of the writing group 2, first, for each proximity mesh region, the pattern density ρ′ (pattern area density) of the pattern arranged in the proximity mesh region is calculated.

Next, for the writing group 2, the proximity effect-corrected dose Dp for correcting the proximity effect is calculated for each proximity mesh region. A correction model of the proximity effect-corrected dose Dp and a calculation method thereof may be similar to the method used in the conventional single beam writing method. However, the back scattering coefficient η₂ is set to a value smaller than the back scattering coefficient η₁. Then, the incident dose d in the case of U=0 is fixed to the threshold dose Dth×1.25. When the incident dose d in the case of U=0 is fixed to the threshold dose Dth×1.25, the value of η₂ is set such that the total dose does not become smaller than the threshold dose at U=1.

The contents of the subsequent steps of the beam irradiation time calculation step (S116), the data processing step (S118), and the writing step (S120) are similar to those in the first embodiment.

As described above, according to the second embodiment, the dimensional error due to the difference in the proximity effect density U can be reduced by performing the weak proximity effect correction also for the writing group 2.

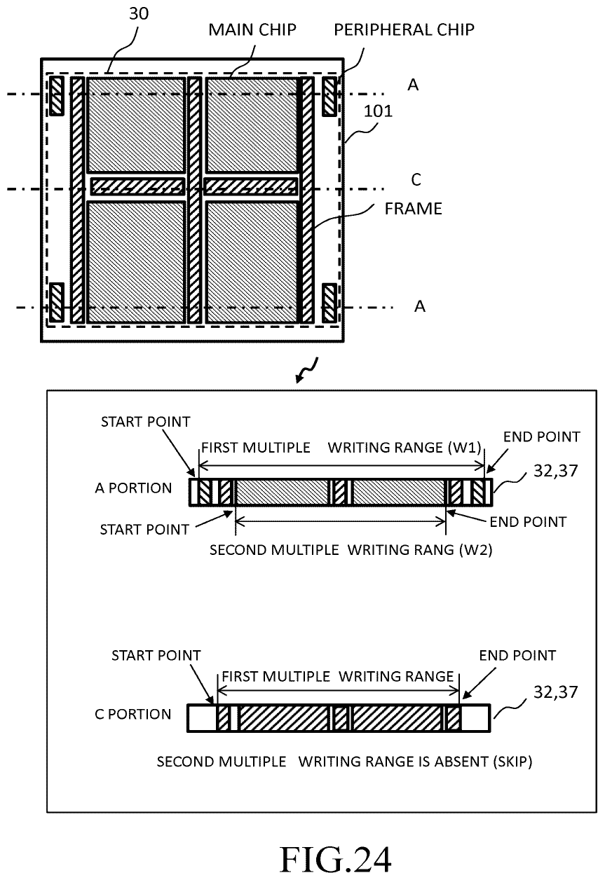

FIG. 24 is a diagram illustrating an example of a pattern formed on a target object in each embodiment. In the example of FIG. 24, a case where the frame is disposed in the main chip in the center portion is illustrated. Specifically, a case where a cross-shaped frame that divides the main chip into four partial chips of upper, lower, left, and right is arranged is illustrated. The rest is similar to that of FIG. 4. In such a case, in the stripe region 32 of the first stripe layer located in the A portion of FIG. 24, the pattern of the peripheral chip, the pattern of the frame, the pattern of the main chip on the left side, the pattern of the frame, the pattern of the main chip on the right side, the pattern of the frame, and the pattern of the peripheral chip are arranged as the stripe group 1 from the left side. Therefore, the start point and the end point are similar to those in the first embodiment. On the other hand, in the stripe region 37 of the second stripe layer located in the A portion of FIG. 24, the pattern of the left main chip and the pattern of the right main chip are arranged as the stripe group 2. The pattern of the frame between the patterns of the left and right main chips is located inside the stripe region 37 of the second stripe layer, but is not included in the writing target in the second stripe layer. That is, the pattern of the frame between the patterns of the left and right main chips is not written when the second stripe layer is scanned.

Therefore, the start point and the end point are similar to those in the first embodiment.

In the stripe region 32 of the first stripe layer located in the C portion of FIG. 24, the pattern of the left frame, the pattern of the center frame, and the pattern of the right frame are arranged as the stripe group 1 from the left side. Therefore, the start point and the end point are similar to those in the first embodiment. On the other hand, since there is no main chip in the stripe region 37 of the second stripe layer located in the C portion of FIG. 24, nothing is arranged. Therefore, the writing of the stripe region 37 is omitted, and the writing is skipped to the stripe region 32 of the next first stripe layer.

As described above, in a case where the writing of some stripe region 37 is omitted, the writing time can be further shortened.

The embodiments have been described with reference to the specific examples. However, the present invention is not limited to these specific examples.

The above-described embodiments are not limited to the case where the XY stage 105 moves at a constant speed at the time of writing, and can also be applied to the case where the XY stage moves at a variable speed.

Further, descriptions of parts and the like that are not directly necessary for explanation of the present invention, such as an apparatus configuration and a control method, have been omitted. However, the necessary apparatus configuration and control method can be appropriately selected and used. For example, although the description of the control unit configuration for controlling the writing apparatus 100 is omitted, it goes without saying that the necessary control unit configuration is appropriately selected and used.

In addition, all charged particle beam writing methods and all charged particle beam writing apparatuses including the elements of the present invention and capable of being appropriately designed and changed by those skilled in the art are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A charged particle beam writing method for writing a plurality of patterns to be written assigned to any one of a plurality of pattern groups, the charged particle beam writing method comprising:
setting a multiplicity of multiple writing to a value different for each pattern group of the plurality of pattern groups; and
writing a plurality of patterns on a target object in accordance with the multiplicity set for each pattern group by using a charged particle beam by performing
processing of writing each pattern of two or more pattern groups among the plurality of pattern groups in one travel in a predetermined direction of a stage on which the target object is placed and
processing of writing no pattern of at least one pattern group less than the two or more pattern groups and writing a pattern of the remaining pattern group of the two or more pattern groups in one travel in the predetermined direction of the stage.

2. The method according to claim 1, wherein
when the multiplicity is set to be variable, the at least one pattern group of the two or more pattern groups is set to have a lower multiplicity than the remaining pattern groups of the two or more pattern groups.

3. The method according to claim 1, wherein
the multiple writing is performed by shifting positions of a plurality of grids on the target object as irradiation positions irradiated with the charged particle beam by a size smaller than a grid width indicating a width between grids of the plurality of grids in at least one writing processing among a plurality of writing processing of performing one writing in multiple writing, and
the grid width is variably controlled for each pattern group by writing the plurality of patterns in accordance with the multiplicity.

4. The method according to claim 3, wherein
the at least one pattern group of the two or more pattern groups is written with a coarser grid width than the remaining pattern groups of the two or more pattern groups.

5. The method according to claim 1, further comprising:
setting two or more sets of a plurality of stripe regions, each set including a plurality of stripe regions obtained by dividing a writing region of the target object into a strip shape, wherein
when a plurality of stripe regions of one set are written, each pattern of two or more pattern groups among the plurality of pattern groups is written, and
when a plurality of stripe regions of another set are written, a pattern of at least one pattern group less than the two or more pattern groups are not written, and a pattern of remaining pattern group of the two or more pattern groups is written.

6. A charged particle beam writing apparatus for writing a plurality of patterns to be written assigned to any one of a plurality of pattern groups, the charged particle beam writing apparatus comprising:
a setting circuit configured to set a multiplicity of multiple writing to a value different for each pattern group of the plurality of pattern groups; and
a writing mechanism configured to write a plurality of patterns on a target object in accordance with the multiplicity set for each pattern group by using a charged particle beam by performing
processing of writing each pattern of two or more pattern groups among the plurality of pattern groups in one travel in a predetermined direction of a stage on which the target object is placed and
processing of writing no pattern of at least one pattern group less than the two or more pattern groups and writing a pattern of the remaining pattern group of the two or more pattern groups in one travel in the predetermined direction of the stage.
